(19) United States
(12) Patent Application Publication
(10) Pub. No.: US 2017/0088719 A1
(43) Pub. Date: Mar. 30, 2017

(54) POLYMER COMPOSITIONS, POLYMER FILMS, AND ELECTRONIC DEVICES CONTAINING SUCH FILMS

(71) Applicant: RHODIA OPERATIONS, Paris (FR)

(72) Inventors: Ahmed ALSAYED, Cherry Hill, NJ (US); Lawrence Alan HOUGH, Yongsan-gu, Seoul (KR); Chantal BADRE, Millstone, NJ (US)

(21) Appl. No.: 15/312,518

(22) PCT Filed: May 21, 2015
(86) PCT No.: PCT/US2015/032008

§ 371 Date: Nov. 18, 2016

Related U.S. Application Data
(60) Provisional application No. 62/001,710, filed on May 22, 2014.

(51) Int. Cl. C09D 5/24; H01L 51/00; C09D 165/00

(52) U.S. Cl. CPC C09D 5/24; C09D 165/00; H01L 51/0037; H01L 51/5206

(57) ABSTRACT

A polymer film containing a mixture of (a) at least one electrically conductive polymer, and (b) at least one organic salt having a melting point of greater than 100 C is made by forming a layer of a polymer composition that contains (a) a liquid carrier comprising water and at least one water miscible polar organic liquid, (b) the at least one electrically conductive polymer dissolved or dispersed in the liquid carrier, and (c) the at least one organic salt having a melting point of greater than 100 C dissolved in the liquid carrier, and (2) removing the liquid carrier from the layer. The polymer film is useful as a layer in a laminar electronic device.

### FIELD OF THE INVENTION

The present invention relates to polymer compositions and films, more particularly polymer compositions and films comprising electrically conductive polymers, and electronic devices containing such polymer films.

### BACKGROUND

Transparent conductors, such as Indium Tin Oxide (ITO), combine the electrical conductivity of metal with the optical transparency of glass and are useful as components in electronic devices, such as in display devices. Flexibility is likely to become a broader challenge for ITO, which does not seem well suited to the next generation of display, lighting, or photovoltaic devices. These concerns have motivated a search for replacements using conventional materials and nanomaterials. There is variety of technical approaches for developing ITO substitutes and there are four areas in which the alternative compete: price, electrical conductivity, optical transparency, and physical resiliency.

Electrically conductive polymers, such as polythiophene polymers, particularly a polymer blend of poly(3,4-ethylenedioxythiophene) and poly(styrene sulfonate) (“PEDOT-PSS”) have been investigated as possible alternatives to ITO. The electrical conductivity of electrically conductive polymers is typically lower than that of ITO, but can be enhanced through the use of conductive fillers, such as carbon nanotubes, and dopants. However, the performance of such films still falls short of that of ITO and trade-offs exist between optimizing the electrical conductivity and optimizing the optical transparency of electrically conductive polymers films.

There is an ongoing unresolved interest in increasing the electrical conductivity and optical transparency of PEDOT-PSS films.

### SUMMARY OF THE INVENTION

In a first aspect, the present invention is directed to a polymer film, comprising a mixture of:
(a) an electrically conductive polymer, and
(b) an organic salt having a melting point of greater than 100° C.

In a second aspect, the present invention is directed to a polymer composition, comprising:
(a) a liquid carrier comprising water and at least one water miscible polar organic liquid,
(b) at least one electrically conductive polymer dissolved or dispersed in the liquid carrier, and
(c) at least one organic salt having a melting point of greater than 100° C. dissolved in the liquid carrier.

In a third aspect, the present invention is directed to a method for making polymer film, comprising:
(1) forming a layer of a polymer composition, said polymer composition comprising
   a) at least one water miscible polar organic liquid,
   (b) at least one electrically conductive polymer, and
   (c) at least one organic salt having a melting point of greater than 100° C., and
(2) removing the liquid carrier from the layer.

In a fourth aspect, the present invention is directed to an electronic device, comprising at least one polymer film according to the present invention.

The respective polymer film of the present invention and polymer film component of the electronic device of the present invention typically provide high electrical conductivity and high optical transmittance.

### BRIEF DESCRIPTION OF THE DRAWINGS

FIG. 1 shows a schematic diagram of an electronic device according to the present invention.

FIG. 2 shows a comparison of the change in Sheet Resistance (in %) vs. ageing time (in days) for the PEDOT:PSS/DMSO/sodium tetrakis (pentafluorophenyl) borate film of Example 6 and the PEDOT:PSS/DMSO film of Comparative Example C2.

### DETAILED DESCRIPTION OF THE INVENTION

As used herein, the following terms have the meanings ascribed below:

“acidic group” means a group capable of ionizing to donate a hydrogen ion,

“anode” means an electrode that is more efficient for injecting holes compared to than a given cathode,

“buffer layer” generically refers to electrically conductive or semiconductive materials or structures that have at least one function in an electronic device, including but not limited to, planarization of an adjacent structure in the device, such as an underlying layer, charge transport and/or charge injection properties, scavenging of impurities such as oxygen or metal ions, and other aspects to facilitate or to improve the performance of the electronic device,

“cathode” means an electrode that is particularly efficient for injecting electrons or negative charge carriers,

“confinement layer” means a layer that discourages or prevents quenching reactions at layer interfaces,

“doped” as used herein in reference to an electrically conductive polymer means that the electrically conductive polymer has been combined with a polymeric counterion for the electrically conductive polymer, which polymeric counterion is referred to herein as “dopant”, and is typically a polymeric acid, which is referred to herein as a “polymeric acid dopant”,

“doped electrically conductive polymer” means a polymer blend comprising an electrically conductive polymer and a polymeric counterion for the electrically conductive polymer,

“electrically conductive polymer” means any polymer or polymer blend that is inherently or intrinsically, without the addition of electrically conductive fillers such as carbon black or conductive metal particles, capable of electrical conductivity, more typically to any polymer or oligomer that exhibits a bulk specific conductance of greater than or equal to 10⁻⁷ Siemens per centimeter (“S/cm”), unless otherwise indicated, a reference herein to an “electrically conductive polymer” include any optional polymeric acid dopant,

“electrically conductive” includes conductive and semi-conductive,

“electroactive” when used herein in reference to a material or structure, means that the material or structure exhibits electronic or electro-radiative properties, such as emitting radiation or exhibiting a change in concentration of electron-hole pairs when receiving radiation,

“electronic device” means a device that comprises one or more layers comprising one or more semiconductor materials and makes use of the controlled motion of electrons through the one or more layers,

“electron injection/transport”, as used herein in reference to a material or structure, means that such material or structure that promotes or facilitates migration of negative charges through such material or structure into another material or structure,

“high-boiling solvent” refers to an organic compound which is a liquid at room temperature and has a boiling point of greater than 100° C.,

“hole transport” when used herein when referring to a material or structure, means such material or structure facilitates migration of positive charges through the thickness of such material or structure with relative efficiency and small loss of charge,

“layer” as used herein in reference to an electronic device, means a coating covering a desired area of the device, wherein the area is not limited by size, that is, the area covered by the layer can, for example, be as large as an entire device, be as large as a specific functional area of the device, such as the actual visual display, or be as small as a single sub-pixel,

“polymer” includes homopolymers and copolymers,

“polymer blend” means a blend of two or more polymers, and

“polymer network” means a three dimensional structure of interconnected segments of one or more polymer molecules, in which the segments are of a single polymer molecule and are interconnected by covalent bonds (a “crosslinked polymer network”), in which the segments are of two or more polymer molecules and are interconnected by means other than covalent bonds, (such as physical entanglements, hydrogen bonds, or ionic bonds) or by both covalent bonds and by means other than covalent bonds (a “physical polymer network”).

As used herein, the terminology “(Cₓ-C_{y})” in reference to an organic group, wherein x and y are each integers, means that the group may contain from x carbon atoms to y carbon atoms per group.

As used herein, the term “alkyl” means a monovalent straight, branched or cyclic saturated hydrocarbon radical, more typically, a monovalent straight or branched saturated (C₁-C₄₀)hydrocarbon radical, such as, for example, methyl, ethyl, n-propyl, isopropyl, n-butyl, isobutyl, tert-butyl, hexyl, octyl, hexadecyl, octadecyl, eicosyl, behenyl, tricontyl, and tetracontyl. As used herein, the term “cycloalkyl” means a saturated hydrocarbon radical, more typically a saturated (C₅-C₂₂) hydrocarbon radical, that includes one or more cyclic alkyl rings, which may optionally be substituted on one or more carbon atoms of the ring with one or two (C₁-C₆)alkyl groups per carbon atom, such as, for example, cyclopentyl, cycloheptyl, cyclooctyl. The term “heteroalkyl” means an alkyl group wherein one or more of the carbon atoms within the alkyl group has been replaced by a hetero atom, such as nitrogen, oxygen, sulfur. The term “alkylene” refers to a divalent alkyl group including, for example, methylene, and poly(methylene).

As used herein, the term “hydroxyalkyl” means an alkyl radical, more typically a (C₁-C₂₂)alkyl radical, that is substituted with one or more hydroxyl groups, including, for example, hydroxymethyl, hydroxyethyl, hydroxypropyl, and hydroxydecyl.

As used herein, the term “alkoxyalkyl” means an alkyl radical that is substituted with one or more alkoxy substituents, more typically a (C₁-C₂₂)alkyloxy-(C₁-C₆)alkyl radical, including, for example, methoxymethyl, and ethoxybutyl.

As used herein, the term “alkenyl” means an unsaturated straight or branched hydrocarbon radical, more typically an unsaturated straight, branched, (C₂-C₂₂) hydrocarbon radical, that contains one or more carbon-carbon double bonds, including, for example, ethenyl, n-propenyl, and iso-propenyl,

As used herein, the term “cycloalkenyl” means an unsaturated hydrocarbon radical, typically an unsaturated (C₅-C₂₂) hydrocarbon radical, that contains one or more cyclic alkenyl rings and which may optionally be substituted on one or more carbon atoms of the ring with one or two (C₁-C₆)alkyl groups per carbon atom, including, for example, cyclohexenyl and cycloheptenyl.

As used herein, the term “aryl” means a monovalent unsaturated hydrocarbon radical containing one or more six-membered carbon rings in which the unsaturation may be represented by three conjugated double bonds, which may be substituted one or more of carbons of the ring with hydroxyl, alkyl, alkoxyl, alkenyl, halo, haloalkyl, monocyclic aryl, or amino, including, for example, phenyl, methylphenyl, methoxyphenyl, dimethylphenyl, trimethylphenyl, chlorophenyl, trichloromethylphenyl, triisobutyl phenyl, tristyrylphenyl, and aminophenyl.

As used herein, the term “aralkyl” means an alkyl group substituted with one or more aryl groups, more typically a (C₁-C₁₈)alkyl substituted with one or more (C₆-C₁₄)aryl substituents, including, for example, phenylmethyl, phenylethyl, and triphenylmethyl.

As used herein, the term “heteroaromatic” refers to compounds having at least one aromatic ring that includes at least one hetero atom in the ring and the term “polycyclic heteroaromatic” refers to compounds having more than one aromatic ring, at least one of which includes at least one hetero atom in the ring, wherein adjacent rings may be linked to each other by one or more bonds or divalent bridging groups or may be fused together.

As used herein, the following terms refer to the corresponding substituent groups:

“amido” is —R¹—C(O)N(R⁶)R⁶,

“amidosulfonate” is —R¹—C(O)N(R⁴)R²—SO₃Z,

“benzyl” is —CH₂—C₆H₅,

“carboxylate” is —R¹—C(O)O—Z or —R¹—O—C(O)—Z,

“ether” is —R¹—(O—R³)ₚ—O—R³,

“ether carboxylate” is —R¹—O—R²—C(O)O—Z or —R¹—O—R²—O—C(O)—Z,

“ether sulfonate” is —R¹—O—R²—SO₃Z,

“ester sulfonate” is —R¹—O—C(O)R²—SO₃Z,

“sulfonimide” is —R¹—SO₂—NH—SO₂—R³, and

“urethane” is —R¹—O—C(O)—N(R⁴)₂,

wherein:

each R¹ is absent or alkylene,

each R² is alkylene,

each R³ is alkyl,

each R⁴ is H or an alkyl,

p is 0 or an integer from 1 to 20, and

each Z is H, alkali metal, alkaline earth metal, N(R³)₄ or R³,

wherein any of the above groups may be non-substituted or substituted, and any group may have fluorine substituted for one or more hydrogens, including perfluorinated groups.

In one embodiment, respective polymer film of the present invention and polymer film component of the electronic device of the present invention each comprise, based on 100 parts by weight (“pbw”) of the polymer film:

(i) from about 1 pbw to about 99.9 pbw, more typically from about 10 pbw to about 90 pbw, and even more typically from about 20 pbw to about 80 pbw of the electrically conductive polymer, and
(ii) from about 0.1 to about 99 pbw, more typically from about 10 to about 90 pbw, and even more typically from about 20 to about 80 pbw of the one or more organic salts,
wherein the ratio of the total amount by weight of the at least one organic salt in such film to the total amount by weight of the electrically conductive polymer in such film is typically from greater than 0:1 to about 1.5:1, more typically from about 0.1:1 to 1:1.

In one embodiment of the respective polymer film of the present invention and polymer film component of the electronic device of the present invention, the polymer network is a physical polymer network formed by non-crosslinked molecules of the electrically conductive polymer.

In one embodiment of the respective polymer film of the present invention and polymer film component of the electronic device of the present invention, the polymer network is a crosslinked polymer network.

In one embodiment, the polymer composition of the present invention comprises, based on 100 pbw of the polymer composition:

(a) from greater than 0 to less than 100 pbw, more typically from about 50 to less than 100 pbw, even more typically from about 90 to about 99.5 pbw of liquid carrier,
(b) from greater than 0 to less than 100 pbw, more typically from greater than 0 to about 50 pbw, even more typically from 0.5 to about 10 pbw, of the mixture of electrically conductive polymer and at least one organic salt, comprising, based on 100 pbw of the total amount of the electrically conductive polymer and the at least one organic salt;
(i) from about 1 to about 99.9 pbw, more typically from about 10 to about 90 pbw, and even more typically from about 20 to about 80 pbw of the electrically conductive polymer, and
(ii) from about 0.1 to about 99 pbw, more typically from about 10 to about 90 pbw, and even more typically from about 20 to about 80 pbw of the at least one organic salt.

The liquid carrier of the polymer composition of the present invention comprises water and one or more water miscible polar organic liquids, and the electrically conductive polymer is dispersible in the liquid carrier.

In one embodiment, the liquid carrier comprises, based on 100 pbw of the liquid medium, from about 5 to less than 95 pbw, more typically from about 20 pbw to 80 pbw, and even more typically, from about 30 to 70 pbw, water, about 5 pbw to about 95 pbw, more typically from 20 pbw to about 80 pbw, and even more typically from 30 pbw to about 70 pbw of the at least one water miscible polar organic liquid.

Suitable polar organic liquids include polar aprotic organic liquids, polar protic organic liquids, and mixtures of two or more of such liquids. In one embodiment, the polar organic liquid comprises a mixture of a polar aprotic solvent and a polar protic solvent.

In one embodiment, the polar organic liquid comprises at least one polar organic liquid having a boiling point of greater than 120° C., more typically greater than 100° C.

Suitable polar aprotic organic solvents include for example, dichloromethane, ethyl acetate, acetone, acetonitrile, dimethyl formamide, dimethyl sulfoxide, tetrahydrofuran, and mixtures thereof.

Suitable polar protic organic solvents, include, for example, (C₁-C₆)alkanols, such as methanol, ethanol, and propanol, glycols, such as ethylene glycol, and mixtures thereof.

In one embodiment, the polymer composition is a polymer solution, wherein the electrically conductive polymer component of the composition is soluble in the liquid medium.

The electrically conductive polymer component of the respective polymer composition, polymer film, and electronic device of the present invention may each comprise one or more homopolymers, one or more co-polymers of two or more respective monomers, or a mixture of one or more homopolymers and one or more copolymers. The respective dispersion, film and electrically conductive polymer film component of the electronic device of the present invention may each comprise a single conductive polymer or may comprise a blend two or more conductive polymers which differ from each other in some respect, for example, in respect to composition, structure, or molecular weight.

In one embodiment, the electrically conductive polymer of the dispersion, film and/or electrically conductive polymer film component of the electronic device of the present invention, comprises one or more electrically conductive polymers selected from electrically conductive polythiophene polymers, electrically conductive poly(selenophene) polymers, electrically conductive poly(telurophene) polymers, electrically conductive polypyrrole polymers, electrically conductive polyaniline polymers, electrically conductive fused polycylic heteroaromatic polymers, and blends of any such polymers.

In one embodiment, the electrically conductive polymer comprises one or more polymers selected from electrically conductive polythiophene polymers, electrically conductive poly(selenophene) polymers, electrically conductive poly(telurophene) polymers, and mixtures thereof Suitable polythiophene polymers, poly(selenophene) polymers, poly(telurophene) polymers and methods for making such polymers are generally known. In one embodiment, the electrically conductive polymer comprises at least one electrically conductive polythiophene polymer, electrically conductive poly(selenophene) polymer, or electrically conductive poly(telurophene) polymer that comprises 2 or more, more typically 4 or more, monomeric units according to structure (I) per molecule of the polymer:

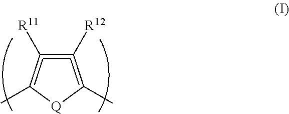

wherein:

Q is S, SE, or Te, and

each occurrence of R¹¹ and each occurrence of R¹² is independently H, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, hydroxyl, hydroxyalkyl, benzyl, carboxylate, ether, ether carboxylate, amidosulfonate, ether sulfonate, ester sulfonate, and urethane, or both the R¹ group and R² group of a given monomeric unit are fused to form, together with the carbon atoms to which they are attached, an alkylene or alkenylene chain completing a 3, 4, 5, 6, or 7-membered aromatic or alicyclic ring, which ring may optionally include one or more divalent nitrogen, selenium, telurium, sulfur, or oxygen atoms.

In one embodiment, Q is S, the R¹¹ and R¹² of the monomeric unit according to structure (I) are fused and the electrically conductive polymer comprises a polydioxythiopene polymer that comprises 2 or more, more typically 4 or more, monomeric units according to structure (I.a) per molecule of the polymer:

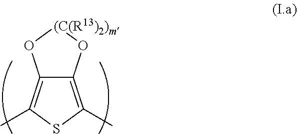

wherein:

each occurrence of R¹³ is independently H, alkyl, hydroxyl, heteroalkyl, alkenyl, heteroalkenyl, hydroxalkyl, amidosulfonate, benzyl, carboxylate, ether, ether carboxylate, ether sulfonate, ester sulfonate, or urethane, and

m′ is 2 or 3.

In one embodiment, all R¹³ groups of the monomeric unit according to structure (I.a) are each H, alkyl, or alkenyl. In one embodiment, R¹³ groups of the monomeric unit according to structure (I.a) is not H. In one embodiment, each R¹³ groups of the monomeric unit according to structure (I.a) is H.

In one embodiment, the electrically conductive polymer comprises an electrically conductive polythiophene homopolymer of monomeric units according to structure (I.a) wherein each R¹³ is H and m′ is 2, known as poly(3,4-ethylenedioxythiophene), more typically referred to as “PEDOT”.

In one embodiment, the electrically conductive polymer comprises one or more electrically conductive polypyrrole polymers. Suitable electrically conductive polypyrrole polymers and methods for making such polymers are generally known. In one embodiment, the electrically conductive polymer comprises a polypyrrole polymer that comprises 2 or more, more typically 4 or more, monomeric units according to structure (II) per molecule of the polymer:

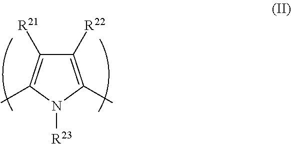

wherein:

each occurrence of R²¹ and each occurrence of R²² is independently H, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, hydroxyl, hydroxyalkyl, benzyl, carboxylate, ether, amidosulfonate, ether carboxylate, ether sulfonate, ester sulfonate, and urethane, or the R²¹ and R²² of a given pyrrole unit are fused to form, together with the carbon atoms to which they are attached, an alkylene or alkenylene chain completing a 3, 4, 5, 6, or 7-membered aromatic or alicyclic ring, which ring may optionally include one or more divalent nitrogen, sulfur or oxygen atoms, and

each occurrence of R²³ is independently selected so as to be the same or different at each occurrence and is selected from hydrogen, alkyl, alkenyl, aryl, alkanoyl, alkylthioalkyl, alkylaryl, arylalkyl, amino, epoxy, silane, siloxane, hydroxyl, hydroxyalkyl, benzyl, carboxylate, ether, ether carboxylate, ether sulfonate, ester sulfonate, and urethane

In one embodiment, each occurrence of R²¹ and each occurrence of R²² is independently H, alkyl, alkenyl, alkoxy, cycloalkyl, cycloalkenyl, hydroxyl, hydroxyalkyl, benzyl, carboxylate, ether, amidosulfonate, ether carboxylate, ether sulfonate, ester sulfonate, urethane, epoxy, silane, siloxane, or alkyl, wherein the alky group may optionally be substituted with one or more of sulfonic acid, carboxylic acid, acrylic acid, phosphoric acid, phosphonic acid, halogen, nitro, cyano, hydroxyl, epoxy, silane, or siloxane moieties.

In one embodiment, each occurrence of R²³ is independently H, alkyl, and alkyl substituted with one or more of sulfonic acid, carboxylic acid, acrylic acid, phosphoric acid, phosphonic acid, halogen, cyano, hydroxyl, epoxy, silane, or siloxane moieties.

In one embodiment, each occurrence of R²¹, R²², and R²³ is H.

In one embodiment, R²¹ and R²² are fused to form, together with the carbon atoms to which they are attached, a 6- or 7-membered alicyclic ring, which is further substituted with a group selected from alkyl, heteroalkyl, hydroxyl, hydroxyalkyl, benzyl, carboxylate, ether, ether carboxylate, ether sulfonate, ester sulfonate, and urethane. In one embodiment, and R²² are fused to form, together with the carbon atoms to which they are attached, a 6- or 7-membered alicyclic ring, which is further substituted with an alkyl group. In one embodiment, R²¹ and R²² are fused to form, together with the carbon atoms to which they are attached, a 6- or 7-membered alicyclic ring, which is further substituted with an alkyl group having at least 1 carbon atom.

In one embodiment, R²¹ and R²² are fused to form, together with the carbon atoms to which they are attached, a —O—(CHR²⁴)n′-O— group, wherein:

each occurrence of R²⁴ is independently H, alkyl, hydroxyl, hydroxyalkyl, benzyl, carboxylate, amidosulfonate, ether, ether carboxylate, ether sulfonate, ester sulfonate, and urethane, and

n′ is 2 or 3.

In one embodiment, at least one R²⁴ group is not hydrogen. In one embodiment, at least one R²⁴ group is a substituent having F substituted for at least one hydrogen. In one embodiment, at least one Y group is perfluorinated.

In one embodiment, the electrically conductive polymer comprises one or more electrically conductive polyaniline polymers. Suitable electrically conductive polyaniline polymers and methods of making such polymers are generally known. In one embodiment, the electrically conductive polymer comprises a polyaniline polymer that comprises 2 or more, more typically 4 or more, monomeric units selected from monomeric units according to structure (III) and monomeric units according to structure (III.a) per molecule of the polymer:

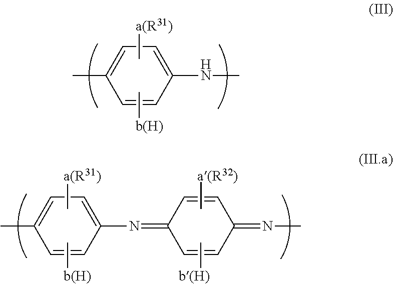

wherein:

each occurrence of R³¹ and R³² s independently alkyl, alkenyl, alkoxy, cycloalkyl, cycloalkenyl, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, carboxylic acid, halogen, cyano, or alkyl substituted with one or more of sulfonic acid, carboxylic acid, halo, nitro, cyano or epoxy moieties, or two R³¹ or R³² groups on the same ring may be fused to form, together with the carbon atoms to which they are attached, a 3, 4, 5, 6, or 7-membered aromatic or alicyclic ring, which ring may optionally include one or more divalent nitrogen, sulfur or oxygen atoms. and each a and a′ is independently an integer from 0 to 4, each b and b′ is integer of from 1 to 4, wherein, for each ring, the sum of the a and b coefficients of the ring or the a′ and b′ coefficients of the ring is 4.

In one embodiment, a or a′=0 and the polyaniline polymer is an non-substituted polyaniline polymers referred to herein as a “PANI” polymer.

In one embodiment, the electrically conductive polymer comprises one or more electrically conductive polycylic heteroaromatic polymers. Suitable electrically conductive polycylic heteroaromatic polymers and methods for making such polymers are generally known. In one embodiment, the electrically conductive polymer comprises one or more polycylic heteroaromatic polymers that comprise 2 or more, more typically 4 or more, monomeric units per molecule that are derived from one or more heteroaromatic monomers, each of which is independently according to Formula (IV):

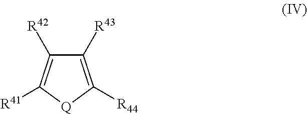

wherein:

Q is S or NH,

R⁴¹, R⁴², R⁴³, and R⁴⁴ are each independently H, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, hydroxyl, hydroxyalkyl, benzyl, carboxylate, ether, ether carboxylate, amidosulfonate, ether sulfonate, ester sulfonate, or urethane, provided that at least one pair of adjacent substituents R⁴¹ and R⁴², R⁴² and R⁴³, or R⁴³ and R⁴⁴ are fused to form, together with the carbon atoms to which they are attached, a 5 or 6-membered aromatic ring, which ring may optionally include one or more hetero atoms, more typically selected from divalent nitrogen, sulfur and oxygen atoms, as ring members.

In one embodiment, the polycylic heteroaromatic polymers comprise 2 or more, more typically 4 or more, monomeric units per molecule that are derived from one or more heteroaromatic monomers, each of which is independently according to structure (V):

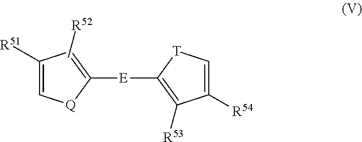

wherein:

Q is S, Se, Te, or NR⁵⁵,

T is S, Se, Te, NR⁵⁵, O, Si(R⁵⁵)₂, or PR⁵⁵,

E is alkenylene, arylene, and heteroarylene,

R⁵⁵ is hydrogen or alkyl,

R⁵¹, R⁵², R⁵³, and R⁵⁴ are each independently H, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, nitrile, cyano, hydroxyl, epoxy, silane, siloxane, hydroxyl, hydroxyalkyl, benzyl, carboxylate, ether, ether carboxylate, amidosulfonate, ether sulfonate, and urethane, or where each pair of adjacent substituents R⁵¹ and R⁵² and adjacent substituents R⁵³ and R⁵⁴ may independently form, together with the carbon atoms to which they are attached, a 3, 4, 5, 6, or 7-membered aromatic or alicyclic ring, which ring may optionally include one or more hetero atoms, more typically selected from divalent nitrogen, sulfur and oxygen atoms, as ring members.

In one embodiment, the electrically conductive polymer comprises an electrically conductive copolymer that comprises at least one first monomeric unit per molecule that is according to formula (I), (I.a), (II), (Ill), or (III.a) or that is derived from a heteroaromatic monomer according to structure (IV) or (V) and further comprises one or more second monomeric units per molecule that differ in structure and/or composition from the first monomeric units. Any type of second monomeric units can be used, so long as it does not detrimentally affect the desired properties of the copolymer. In one embodiment, the copolymer comprises, based on the total number of monomer units of the copolymer, less than or equal to 50%, more typically less than or equal to 25%, even more typically less than or equal to 10% of second monomeric units.

Exemplary types of second monomeric units include, but are not limited to those derived from alkenyl, alkynyl, arylene, and heteroarylene monomers, such as, for example, fluorene, oxadiazole, thiadiazole, benzothiadiazole, phenylene vinylene, phenylene ethynylene, pyridine, diazines, and triazines, all of which may be further substituted, that are copolymerizable with the monomers from which the first monomeric units are derived.

In one embodiment, the electrically conductive copolymers are made by first forming an intermediate oligomer having the structure A-B-C, where A and C represent first monomeric units, which can be the same or different, and B represents a second monomeric unit. The A-B-C intermediate oligomer can be prepared using standard synthetic organic techniques, such as Yamamoto, Stille, Grignard metathesis, Suzuki and Negishi couplings. The electrically conductive copolymer is then formed by oxidative polymerization of the intermediate oligomer alone, or by copolymerization of the intermediate oligomer with one or more additional monomers.

In one embodiment, the electrically conductive polymer comprises an electrically conductive copolymer of two or more monomers. In one embodiment, the monomers comprise at least one monomer selected from a thiophene monomer, a pyrrole monomer, an aniline monomer, and a polycyclic aromatic monomer.

In one embodiment, the weight average molecular weight of the electrically conductive polymer is from about 1000 to about 2,000,000 grams per mole, more typically from about 5,000 to about 1,000,000 grams per mole, and even more typically from about 10,000 to about 500,000 grams per mole.

In one embodiment, the electrically conductive polymer of the respective polymer composition, polymer film, and electronic device of the present invention further comprises a polymeric acid dopant, typically (particularly where the liquid medium of the polymer composition is an aqueous medium), a water soluble polymeric acid dopant. In one embodiment, the electrically conductive polymers used in the new compositions and methods are prepared by oxidatively polymerizing the corresponding monomers in aqueous solution containing a water soluble acid, typically a water-soluble polymeric acid. In one embodiment, the acid is a polymeric sulfonic acid. Some non-limiting examples of the acids are poly(styrenesulfonic acid) (“PSSA”), poly(2-acrylamido-2-methyl-1-propanesulfonic acid) (“PAAMPSA”), and mixtures thereof. The acid anion provides the dopant for the conductive polymer. The oxidative polymerization is carried out using an oxidizing agent such as ammonium persulfate, sodium persulfate, and mixtures thereof. Thus, for example, when aniline is oxidatively polymerized in the presence of PMMPSA, the doped electrically conductive polymer blend PANI/PAAMPSA is formed. When ethylenedioxythiophene (EDT) is oxidatively polymerized in the presence of PSSA, the doped electrically conductive polymer blend PEDT/PSS is formed. The conjugated backbone of PEDT is partially oxidized and positively charged. Oxidatively polymerized pyrroles and thienothiophenes also have a positive charge which is balanced by the acid anion.

In one embodiment, the water soluble polymeric acid selected from the polysulphonic acids, more typically, poly(styrene sulfonic acid), or poly(acrylamido-2-methyl-1-propane-sulfonic acid), or a polycarboxylic acid, such as polyacrylic acid polymethacrylic acid, or polymaleic acid.

In one embodiment, the electrically conductive polymer component of the respective polymer film, polymer solution or dispersion, and/or electronic device of the present invention, comprises, based on 100 pbw of the electrically conductive polymer:
(i) from greater than 0 pbw to 100 pbw, more typically from about 10 to about 50 pbw, and even more typically from about 20 to about 50 pbw, of at least one electrically conductive polymer, more typically of at least one electrically conductive polymer comprising monomeric units according to structure (I.a), more typically at least one polythiophene polymer comprising monomeric units according to structure (I.a), wherein Q is S, and even more typically of at least one electrically conductive polymer comprising poly(3,4-ethylenedioxythiophene), and
(ii) from 0 pbw to 100 pbw, more typically from about 50 to about 90 pbw, and even more typically from about 50 to about 80 pbw, of at least one water soluble polymeric acid dopant, more typically of at least one water soluble polymeric acid dopant comprising a poly(styrene sulfonic acid) dopant.

Suitable organic salts having a melting point of greater than 100° C. comprise an anion and a cation wherein at least one of the anion or cation is an organic moiety, and include organic salts having an inorganic anion and an organic cation, organic salts having an organic anion and an inorganic cation, and organic salts having an organic anion and an organic cation.

In one embodiment, at least one of the anion or cation of the organic salt having a melting point of greater than 100° C. is an organic moiety that in which the electrons are delocalized electrons and the moiety is stabilized by the presence of conjugated double bonds and/or electronegative substituents, such as:

an organic moiety that comprises at least one unsaturated 5 or 6 membered ring, which may optionally include one or more hetero atoms, typically selected from O, S, and N, as members of the ring, and which may optionally which may be substituted one or more of the carbon atoms of the ring with hydroxyl, alkyl, alkoxyl, alkenyl, halo, haloalkyl, monocyclic aryl, or amino, or a non-cyclic organic moiety that comprises at least one, more typically two or more, electronegative heteroatomic substituents, typically N, O, F, P, S, Cl, Se, or Br.

Suitable inorganic anions include halide anions, such as F⁻, Cl⁻, Br⁻, I⁻, and suitable inorganic cations include alkali metal cations, such as Li⁺, Na⁺, or K⁺.

Suitable organic anions include, for example:

borate anions, such as, for example, tetrafluoroborate, tetrakis(pentafluorophenyl) borate, tetracyanoborate, tetrakis-[p-{dimethyl(1H, 1H, 2H, 2H-per-fluorooctly)silyl}phenyl]borate, alkyltrifluoroborate, perfluoroalkyltrifluoroborate, alkenyltrifluoroborate, and tetrakis (pentafluorophenyl) borate anions

carboxylate anions, such as, for example, salicylate, thiosalicylate, L-lactate, acetate, trifluroacetate, and formate anions,

cyanate anions, such as, for example, thiocyanate, dicyanamide, and tricyanomethane anions,

organophosphate anions, such as, for example, di(trifluromethyl)tetrafluorophosphate, tris(trifluoromethyl)trifluorophosphate, tris(perfluoroalkyl)trifluorophosphate, tetra(trifluoromethyl)difluorophosphate, penta(trifluoromethyl)fluorphosphate, and hexa(trifluoromethylphosphate anions,

sulfate and sulfonate anions, such as, for example, trifluoromethanesulfonate, aryl sulfonates, such as 3-nitrobenzene sulfonate, p-toluene sulfonate, and benzene-1,3-disulfonate, hydrogen sulfate, tosylate, (C₁-C₁₂)alkylsulfate, and (C₁-C₁₂)alkylsulfonate anions,

perfluoroalkyl β-diketonate anions, such as, for example, 6,6,7,7,8,8,8-heptafluoro-2,2-dimethyl-3,5-octanedionate, 1,1,1,5,5,5-hexafluoro-2,4-pentanedionate, 4,4,4-trifluoro-1-(2-thienyl)-1,3-butanedionate anions.

Suitable organic cations include, for example:

morpholinium cations, such as, for example, morpholinium, N-methyl-morpholinium, and N-ethyl-morpholinium cations,

phosphonium cations, such as for example, phosphonium, tetrabutyl phosphonium, and tributylmethyl phosphonium cations,

piperidinium cations, such as, for example, piperidinium, 1-butyl-1-methyl-piperidinium, and 1-methyl-1-propyl-piperidinium cations, pyradazinium cations,

pyrazinium cations, such as, for example, pyrazinium, 1-ethyl-4-methyl-pyrazinium, and 1-octyl-4-propyl-pyrazinium cations,

pyrazolium cations, such as, for example, pyrazolinium and 1-ethyl-2,3,5-pyrazolinium cations,

pyridinium cations, such as for example, pyridinium, N-butyl-pyridinium, and N-hexyl-pyridinium cations,

pyrimidinium cations, such as, for example, pyrimidinium, 1-hexyl-3-propyl-pyrimidinium, and 1-ethyl-3-methyl-pyrimidinium cations,

pyrrolidinium cations, such as for example, pyrrolidinium, 1-butyl-1-methyl-pyrrolidinium, and 1-methyl-1-propyl-pyrrolidinium cations,

pyrrolium cations, such as for example, pyrrolium, 1,1-dimethyl-pyrrolium, and 1-methyl-1-pentyl-pyrrolium cations,

pyrrolinium cations,

sulfonium cations, such as, for example, sulfonium and trimethyl sulfonium cations,

thiazolium cations,

oxazolium cations, and

triazolium cations,

In one embodiment, the organic salt is selected from pyridinium p-toluene sulfonate, pyridinium tribromide, pyridunium 3-nitrobenzene sulfonate, sodium benzene-1,3-disulfonate, sodium tetrakis (pentafluorophenyl) borate, and mixtures thereof.

The composition of the present invention may optionally further comprise electrically conductive nanostructures. As used herein, the term “nanostructures” generally refers to nano-sized structures, at least one dimension of which is less than or equal to 500 nm, more typically, less than or equal to 250 nm, or less than or equal to 100 nm, or less than or equal to 50 nm, or less than or equal to 25 nm.

The electrically conductive nanostructures can be of any shape or geometry, more typically of anisotropic geometry. Typical anisotropic nanostructures include nanofibers, nanowires and nanotubes.

The electrically conductive nanostructures can be formed of any electrically conductive material, such as for example, metallic materials or non-metallic materials, such as carbon or graphite, and may comprise a mixture of nanostructures formed form different electrically conductive materials, such as a mixture of carbon fibers and silver nanowires.

In one embodiment, the polymer dispersion, polymer film, and polymer film component of the electronic device of the present invention further comprise one or more metallic electrically conductive nanostructures, such as, for example, silver nanowires or silver nanotubes,

In one embodiment, the polymer dispersion, polymer film, and polymer film component of the electronic device of the present invention further comprise one or more non-metallic electrically conductive nanostructures, such as, for example, graphite particles, including graphite fibers, or carbon particles, including carbon fullerenes and carbon nanotubes, and as well as combinations of any such additives, in addition to the anisotropic electrically conductive nanostructure component. Suitable fullerenes include for example, C60, C70, and C84 fullerenes, each of which may be derivatized, for example with a (3-methoxycarbonyl)-propyl-phenyl (“PCBM”) group, such as C60-PCBM, C-70-PCBM and C-84 PCBM derivatized fullerenes. Suitable carbon nanotubes include single wall carbon nanotubes having an armchair, zigzag or chiral structure, as well as multiwall carbon nanotubes, including double wall carbon nanotubes, and mixtures thereof.

In one embodiment, the respective polymer dispersion, polymer film, and polymer film component of the electronic device of the present invention further comprises one or more additional components, such as, for example one or more of polymers, dyes, coating aids, conductive particles, conductive inks, conductive pastes, charge transport materials, crosslinking agents, and combinations thereof, that are dissolved or dispersed in the liquid carrier.

In one embodiment, the aqueous dispersion of the present invention is made by mixing water and the water miscible polar organic liquid to form the liquid carrier, dispersing the electrically conductive polymer in the liquid carrier, and dissolving the organic salt in the liquid carrier.

In one embodiment, an electrically conductive polymer film according to the present invention is made by:
(1) forming a layer of a polymer composition, said polymer composition comprising;
   (a) a liquid carrier comprising water and at least one water miscible polar organic liquid,
   (b) at least one electrically conductive polymer dissolved or dispersed in the liquid carrier, and
   (c) at least one organic salt having a melting point of greater than 100° C. dissolved in the liquid carrier, and
(2) removing the liquid carrier from the layer.

In one embodiment, the layer of polymer composition is formed by, for example, casting, spray coating, spin coating, gravure coating, curtain coating, dip coating, slot-die coating, ink jet printing, gravure printing rod coating, doctor-blade coating, or screen printing, on a substrate. Typically, the liquid carrier is removed from the layer by allowing the liquid carrier component of the layer to evaporate. The substrate supported layer may, optionally, be subjected to elevated temperature to encourage evaporation of the liquid carrier.

The substrate may be rigid or flexible and may comprise, for example, a metal, a polymer, a glass, a paper, or a ceramic material. In one embodiment, the substrate is a flexible plastic sheet.

The polymer film may cover an area of the substrate that is as large as an entire electronic device or as small as a specific functional area such as the actual visual display, or as small as a single sub-pixel. In one embodiment, the polymer film has a thickness of from greater than 0 to about 10 μm, more typically from 0 to about 50 nm.

In another embodiment, an electrically conductive polymer film according to the present invention is made by:
(1) forming a layer of a polymer composition, said polymer composition comprising;
   (a) a liquid carrier comprising water and, optionally, at least one water miscible polar organic liquid,
   (b) at least one electrically conductive polymer dissolved or dispersed in the liquid carrier,
(2) removing the liquid carrier from the layer to form a polymer film,
(3) contacting the polymer film with a solution of at least one organic salt having a melting point of greater than 100° C. in a second liquid carrier, wherein the second liquid carrier comprises water, at least one water miscible polar organic liquid, or a mixture of water and at least one water miscible polar organic liquid, and
(4) removing the liquid carrier from the polymer film.

In another embodiment, an electrically conductive polymer film according to the present invention is made by:
(1) providing a film of an electrically conductive polymer,
(3) contacting the film with a solution of at least one organic salt having a melting point of greater than 100° C. in a liquid carrier, wherein the liquid carrier comprises water, at least one water miscible polar organic liquid, or a mixture of water and at least one water miscible polar organic liquid, and
(4) removing the liquid carrier from the polymer film.

In one embodiment, the polymer film of the present invention is not redispersible in the liquid carrier, and the film can thus be applied as a series of multiple thin films. In addition, the film can be overcoated with a layer of different material dispersed in the liquid carrier without being damaged.

In one embodiment, the polymer composition of the present invention comprises, based on 100 pbw of the polymer composition:
(i) from greater than 0 to less than 100 pbw, more typically from about 50 to less than 100 pbw, even more typically from about 90 to about 99.5 pbw of a liquid carrier, comprising, based on 100 pbw of the liquid medium, from about 5 to less than 95 pbw, more typically from about 20 pbw to 80 pbw, and even more typically, from about 30 to 70 pbw, water, about 5 pbw to about 95 pbw, more typically from 20 pbw to about 80 pbw, and even more typically from 30 pbw to about 70 pbw of the at least one water miscible polar organic liquid,
(ii) from greater than 0 to less than 100 pbw, more typically from greater than 0 to about 50 pbw, even more typically from about 0.1 pbw to about 10 pbw of a combined amount of the at least one electrically conductive polymer and the at least one organic salt, comprising, based on the combined amount of the electrically conductive polymer and organic salt:
   (a) from about 1 to about 99.9 pbw, more typically from about 10 to about 90 pbw, and even more typically 20 to about 80 pbw of the electrically conductive polymer, more typically of an electrically conductive polymer comprising, based on 100 pbw of the electrically conductive polymer:
      (1) from greater than 0 pbw to 100 pbw, more typically from about 10 to about 50 pbw, and even more typically from about 20 to about 50 pbw of at least one polythiophene polymer comprising monomeric units according to structure (I.a) wherein Q is S, and more typically, at least one polythiophene polymer comprising poly(3,4-ethylenedioxythiophene), and
      (2) from 0 pbw to 100 pbw, more typically from about 50 to about 90 pbw, and even more typically from about 50 to about 80 pbw, of at least one water soluble polymeric acid dopant, more typically of at least one water soluble polymeric acid dopant comprising a poly(styrene sulfonic acid) dopant, and
   (b) from about 0.1 pbw to about 99 pbw, more typically from about 10 pbw to about 90 pbw, and even more typically from about 20 pbw to about 80 pbw, of at least one organic salt more typically, of at least one organic salt comprising pyridinium p-toluene sulfonate, pyridinium tribromide, pyridunium 3-nitrobenzene sulfonate, sodium benzene-1,3-disulfonate, sodium tetrakis (pentafluorophenyl) borate, or a mixture thereof, wherein the ratio of the total amount by weight of the at least one organic salt in such film to the total amount by weight of the electrically conductive polymer in such film is typically from greater than 0:1 to about 1.5:1, more typically from about 0.1:1 to 1:1.

In one embodiment, the respective polymer film the present invention and polymer film component of the electronic device of the present invention comprises, based on 100 parts by weight of the polymer film:
(a) from about 1 to about 99.9 pbw, more typically from about 10 to about 90 pbw, more typically 20 to about 80 pbw, of the at least one electrically conductive polymer, more typically of an electrically conductive polymer comprising, based on 100 pbw of the electrically conductive polymer:
   (1) from greater than 0 pbw to 100 pbw, more typically from about 10 to about 50 pbw, and even more typically from about 20 to about 50 pbw of at least one polythiophene polymer comprising monomeric units according to structure (I.a) wherein Q is S, and more typically, at least one polythiophene polymer comprising poly(3,4-ethylenedioxythiophene), and
   (2) from 0 pbw to 100 pbw, more typically from about 50 to about 90 pbw, and even more typically from about 50 to about 80 pbw, of at least one water soluble polymeric acid dopant, more typically of at least one water soluble polymeric acid dopant comprising a poly(styrene sulfonic acid) dopant, and
(b) from about 0.1 pbw to about 99 pbw, more typically from about 10 pbw to about 90 pbw, and even more typically from about 20 pbw to about 80 pbw, of at least one organic salt, even more typically at least one organic salt comprising pyridinium p-toluene sulfonate, pyridinium tribromide, pyridunium 3-nitrobenzene sulfonate, sodium benzene-1,3-disulfonate, sodium tetrakis (pentafluorophenyl) borate, or a mixture thereof, wherein the ratio of the total amount by weight of the at least one organic salt in such film to the total amount by weight of the electrically conductive polymer in such film is typically from greater than 0:1 to about 1.5:1, more typically from about 0.1:1 to 1:1.

In one embodiment, the respective polymer film the present invention and polymer film component of the electronic device of the present invention comprises, based on 100 pbw of the polymer film:
(a) from about 5 to about 99.9 pbw, more typically from about 10 to about 90 pbw, and even more typically 20 to about 80 pbw of at least one electrically conductive polymer, comprising, based on 100 pbw of the electrically conductive polymer:
   (1) from about 20 to about 50 pbw of poly(3,4-ethylenedioxythiophene), and
   (2) from about 50 to about 80 pbw of poly(styrene sulfonic acid) dopant, and
(b) from about 0.1 to 99 pbw, more typically from about 10 to 90 pbw, even more typically from about 20 to 80 pbw of the at least one organic salt, more typically, of at least one organic salt, more typically, at least one organic salt comprising pyridinium p-toluene sulfonate, pyridinium tribromide, pyridunium 3-nitrobenzene sulfonate, sodium benzene-1,3-disulfonate, sodium tetrakis (pentafluorophenyl) borate, or a mixture thereof, wherein the ratio of the total amount by weight of the at least one organic salt in such film to the total amount by weight of the electrically conductive polymer in such film is typically from greater than 0:1 to about 1.5:1, more typically from about 0.1:1 to 1:1.

The polymer film according to the present invention typically exhibits high conductivity and high optical transparency and is useful as a layer in an electronic device in which the high conductivity is desired in combination with optical transparency.

In one embodiment, the respective polymer film of the present invention and polymer film component of the electronic device of the present invention each exhibit a sheet resistance of less than or equal to 1000 Ohms per square (“Ω/□”), or less than or equal to 100Ω/□, or less than or equal to 20Ω/□, or less than or equal to 15Ω/□, or less than or equal to 10Ω/□, or less than or equal to 5Ω/□, or less than or equal to 1Ω/□, or less than or equal to 0.1Ω/□.

In one embodiment, the respective polymer film of the present invention and polymer film component of the electronic device of the present invention each exhibit an optical transmittance at 550 nm of greater than or equal to 1%, or greater than or equal to 50%, or greater than or equal to 70%, or greater than or equal to 80%, or greater than or equal to 90%.

In one embodiment, the respective polymer film of the present invention and polymer film component of the electronic device of the present invention each exhibit a sheet resistance of less than or equal to 1000Ω/□ or less than or equal to 100Ω/□, or less than or equal to 20Ω/□, or less than or equal to 15Ω/□, or less than or equal to 10Ω/□, or less than or equal to 5Ω/□, or less than or equal to 1Ω/□, or less than or equal to 0.1Ω/□ and an optical transmittance at 550 nm of greater than or equal to 1%, or greater than or equal to 50%, or greater than or equal to 70%, or than or equal to 80%, or greater than or equal to 90%.

In one embodiment, the respective polymer film of the present invention and polymer film component of the electronic device of the present invention each exhibit a sheet resistance of less than or equal to 100Ω and an optical transmittance at 550 nm of greater than or equal to 90%.

In one embodiment, the respective polymer film of the present invention and polymer film component of the electronic device of the present invention each exhibit a sheet resistance of less than or equal to 15Ω and an optical transmittance at 550 nm of greater than or equal to 70%.

In one embodiment, the respective polymer film of the present invention and polymer film component of the electronic device of the present invention each exhibit a sheet resistance of less than or equal to 5Ω/□ and an optical transmittance at 550 nm of greater than or equal to 50%.

In one embodiment, polymer film according to the present invention is used as an electrode layer, more typically, an anode layer, of an electronic device.

In one embodiment, the polymer film according to the present invention is used as a buffer layer of an electronic device.

In one embodiment, a polymer film according to the present invention is used as a combined electrode and buffer layer, typically a combined anode and buffer layer, of an electronic device.

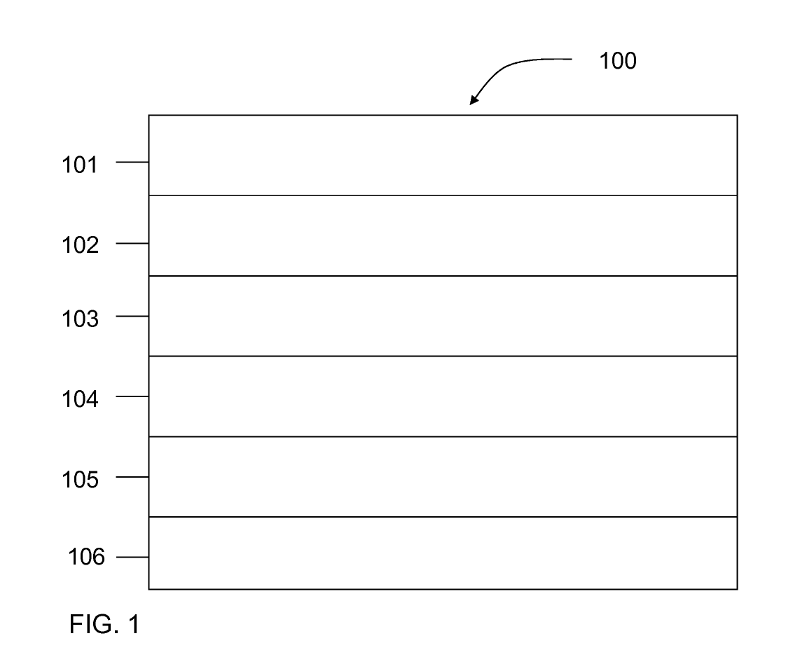

In one embodiment, the electronic device of the present invention is an electronic device 100, as shown in FIG. 1, having an anode layer 101, an electroactive layer 104, and a cathode layer 106 and optionally further having a buffer layer 102, hole transport layer 103, and/or electron injection/transport layer or confinement layer 105, wherein at least one of the layers of the device is a polymer film according to the present invention. The device 100 may further include a support or substrate (not shown), that can be adjacent to the anode layer 101 or the cathode layer 106. more typically, adjacent to the anode layer 101. The support can be flexible or rigid, organic or inorganic. Suitable support materials include, for example, glass, ceramic, metal, and plastic films.

In one embodiment, anode layer 101 of device 100 comprises a polymer film according to the present invention. The polymer film of the present invention is particularly suitable as anode layer 106 of device 100 because of its high electrical conductivity.

In one embodiment, anode layer 101 itself has a multilayer structure and comprises a layer of the polymer film according to the present invention, typically as the top layer of the multilayer anode, and one or more additional layers, each comprising a metal, mixed metal, alloy, metal oxide, or mixed oxide. Suitable materials include the mixed oxides of the Group 2 elements (i.e., Be, Mg, Ca, Sr, Ba, Ra), the Group 11 elements, the elements in Groups 4, 5, and 6, and the Group 8-10 transition elements. If the anode layer 101 is to be light transmitting, mixed oxides of Groups 12, 13 and 14 elements, such as indium-tin-oxide, may be used. As used herein, the phrase “mixed oxide” refers to oxides having two or more different cations selected from the Group 2 elements or the Groups 12, 13, or 14 elements. Some non-limiting, specific examples of materials for anode layer 101 include, but are not limited to, indium-tin-oxide (“ITO”), indium-zinc-oxide, aluminum-tin-oxide, gold, silver, copper, and nickel. The mixed oxide layer may be formed by a chemical or physical vapor deposition process or spin-cast process. Chemical vapor deposition may be performed as a plasma-enhanced chemical vapor deposition (“PECVD”) or metal organic chemical vapor deposition (“MOCVD”). Physical vapor deposition can include all forms of sputtering, including ion beam sputtering, as well as e-beam evaporation and resistance evaporation. Specific forms of physical vapor deposition include radio frequency magnetron sputtering and inductively-coupled plasma physical vapor deposition (“IMP-PVD”). These deposition techniques are well known within the semiconductor fabrication arts.

In one embodiment, the mixed oxide layer is patterned. The pattern may vary as desired. The layers can be formed in a pattern by, for example, positioning a patterned mask or resist on the first flexible composite barrier structure prior to applying the first electrical contact layer material. Alternatively, the layers can be applied as an overall layer (also called blanket deposit) and subsequently patterned using, for example, a patterned resist layer and wet chemical or dry etching techniques. Other processes for patterning that are well known in the art can also be used.

In one embodiment, device 100 comprises a buffer layer 102 and the buffer layer 102 comprises a polymer film according to the present invention.

In one embodiment, a separate buffer layer 102 is absent and anode layer 101 functions as a combined anode and buffer layer. In one embodiment, the combined anode/buffer layer 101 comprises a polymer film according to the present invention.

In some embodiments, optional hole transport layer 103 is present, either between anode layer 101 and electroactive layer 104, or, in those embodiments that comprise buffer layer 102, between buffer layer 102 and electroactive layer 104. Hole transport layer 103 may comprise one or more hole transporting molecules and/or polymers. Commonly used hole transporting molecules include, but are not limited to: 4,4′,4″-tris(N,N-diphenyl-amino)-triphenylamine (TDATA), 4,4′,4″-tris(N-3-methylphenyl-N-phenyl-amino)-triphenylamine (MTDATA), N,N′-diphenyl-N,N′-bis(3-methylphenyl)-[1,1′-biphenyl]-4,4′-diamine (TPD), 1,1-bis[(di-4-tolylamino)phenyl]cyclohexane (TAPC), N,N′-bis(4-methylphenyl)-N,N′-bis(4-ethylphenyl)-[1,1′-(3,3′-dimethyl)bip-henyl]-4,4′-diamine (ETPD), tetrakis-(3-methylphenyl)-N,N,N′,N′-2,5-phenylenediamine (PDA), .alpha.-phenyl-4-N,N-diphenylaminostyrene (TPS), p-(diethylamino)benzaldehyde diphenylhydrazone (DEH), triphenylamine (TPA), bis[4-(N,N-diethylamino)-2-methylphenyl](4-methylphenyl)methane (MPMP), 1-phenyl-3-[p-(diethylamino)styryl]-5-[p-(diethylamino)phenyl]pyr-azoline (PPR or DEASP), 1,2-trans-bis(9H-carbazol-9-yl)cyclobutane (DCZB), N,N,N′,N′-tetrakis(4-methylphenyl)-(1,1′-biphenyl)-4,4′-diamine (TTB), N,N′-bis(naphthalen-1-yl)-N,N′-bis-(phenyl)benzidine (.alpha.-NPB), and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules, such as those mentioned above, into polymers such as polystyrene and polycarbonate.

The composition of electroactive layer 104 depends on the intended function of device 100, for example, electroactive layer 104 can be a light-emitting layer that is activated by an applied voltage (such as in a light-emitting diode or light-emitting electrochemical cell), or a layer of material that responds to radiant energy and generates a signal with or without an applied bias voltage (such as in a photodetector). In one embodiment, electroactive layer 104 comprises an organic electroluminescent (“EL”) material, such as, for example, electroluminescent small molecule organic compounds, electroluminescent metal complexes, and electroluminescent conjugated polymers, as well as mixtures thereof. Suitable EL small molecule organic compounds include, for example, pyrene, perylene, rubrene, and coumarin, as well as derivatives thereof and mixtures thereof. Suitable EL metal complexes include, for example, metal chelated oxinoid compounds, such as tris(8-hydroxyquinolate)aluminum, cyclo-metallated iridium and platinum electroluminescent compounds, such as complexes of iridium with phenylpyridine, phenylquinoline, or phenylpyrimidine ligands as disclosed in Petrov et al., U.S. Pat. No. 6,670,645, and organometallic complexes such as those described in, for example, Published PCT Applications WO 03/008424, WO 03/091688, and WO 03/040257, as well as mixtures any of such EL metal complexes. Examples of EL conjugated polymers include, but are not limited to poly(phenylenevinylenes), polyfluorenes, poly(spirobifluorenes), polythiophenes, and poly(p-phenylenes), as well as copolymers thereof and mixtures thereof.

Optional layer 105 can function as an electron injection/transport layer and/or a confinement layer. More specifically, layer 105 may promote electron mobility and reduce the likelihood of a quenching reaction if layers 104 and 106 would otherwise be in direct contact. Examples of materials suitable for optional layer 105 include, for example, metal chelated oxinoid compounds, such as bis(2-methyl-8-quinolinolato)(para-phenyl-phenolato)aluminum(III) (BAIQ) and tris(8-hydroxyquinolato)aluminum, tetrakis(8-hydroxyquinolinato)zirconium, azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI), quinoxaline derivatives such as 2,3-bis(4-fluorophenyl)quinoxaline, phenanthroline derivatives such as 9,10-diphenylphenanthroline (DPA) and 2,9-dimethyl-4,7-diphenyl-1,10-phenanthroline (DDPA), and as well as mixtures thereof. Alternatively, optional layer 105 may comprise an inorganic material, such as, for example, BaO, LiF, Li₂O.

Cathode layer 106 can be any metal or nonmetal having a lower work function than anode layer 101. In one embodiment, anode layer 101 has a work function of greater than or equal to about 4.4 eV and cathode layer 106 has a work function less than about 4.4 eV. Materials suitable for use as cathode layer 106 are known in the art and include, for example, alkali metals of Group 1, such as Li, Na, K, Rb, and Cs, Group 2 metals, such as, Mg, Ca, Ba, Group 12 metals, lanthanides such as Ce, Sm, and Eu, and actinides, as well as aluminum, indium, yttrium, and combinations of any such materials. Specific non-limiting examples of materials suitable for cathode layer 106 include, but are not limited to, Barium, Lithium, Cerium, Cesium, Europium, Rubidium, Yttrium, Magnesium, Samarium, and alloys and combinations thereof. Cathode layer 106 is typically formed by a chemical or physical vapor deposition process. In some embodiments, the cathode layer will be patterned, as discussed above in reference to the anode layer 101.

In one embodiment, an encapsulation layer (not shown) is deposited over cathode layer 106 to prevent entry of undesirable components, such as water and oxygen, into device 100. Such components can have a deleterious effect on electroactive layer 104. In one embodiment, the encapsulation layer is a barrier layer or film. In one embodiment, the encapsulation layer is a glass lid.

Though not shown in FIG. 1, it is understood that device 100 may comprise additional layers. Other layers that are known in the art or otherwise may be used. In addition, any of the above-described layers may comprise two or more sub-layers or may form a laminar structure. Alternatively, some or all of anode layer 101, buffer layer 102, hole transport layer 103, electron transport layer 105, cathode layer 106, and any additional layers may be treated, especially surface treated, to increase charge carrier transport efficiency or other physical properties of the devices. The choice of materials for each of the component layers is typically determined by balancing the goals of providing a device with high device efficiency with device operational lifetime considerations, fabrication time and complexity factors and other considerations appreciated by persons skilled in the art. It will be appreciated that determining optimal components, component configurations, and compositional identities would be routine to those of ordinary skill of in the art.

The various layers of the electronic device can be formed by any conventional deposition technique, including vapor deposition, liquid deposition (continuous and discontinuous techniques), and thermal transfer. Continuous deposition techniques, include but are not limited to, spin coating, gravure coating, curtain coating, dip coating, slot-die coating, spray coating, and continuous nozzle coating. Discontinuous deposition techniques include, but are not limited to, ink jet printing, gravure printing, and screen printing. Other layers in the device can be made of any materials which are known to be useful in such layers upon consideration of the function to be served by such layers.

In one embodiment of the device 100, the different layers have the following range of thicknesses:

anode layer 101, typically 500-5000 Angstroms (“A”), more typically, 1000-2000 Å,

optional buffer layer 102: typically 50-2000 Å, more typically, 200-1000 Å,

optional hole transport layer 103: typically 50-2000 Å, more typically, 100-1000 Å,

photoactive layer 104: typically, 10-2000 Å, more typically, 100-1000 Å, optional electron transport layer: typically 105, 50-2000 Å, more typically, 100-1000 Å, and

cathode layer 106: typically 200-10000 Å, more typically, 300-5000 Å.

As is known in the art, the location of the electron-hole recombination zone in the device, and thus the emission spectrum of the device, can be affected by the relative thickness of each layer. The appropriate ratio of layer thicknesses will depend on the exact nature of the device and the materials used.

In one embodiment, the electronic device of the present invention, comprises:
(a) an anode or combined anode and buffer layer 101,
(b) a cathode layer 106,
(c) an electroactive layer 104, disposed between anode layer 101 and cathode layer 106,
(d) optionally, a buffer layer 102, typically disposed between anode layer 101 and electroactive layer 104,
(e) optionally, a hole transport layer 105, typically disposed between anode layer 101 and electroactive layer 104, or if buffer layer 102 is present, between buffer layer 102 and electroactive layer 104, and
(f) optionally an electron injection layer 105, typically disposed between electroactive layer 104 and cathode layer 106, wherein at least one of the layers of the device, typically at least one of the anode or combined anode and buffer layer 101 and, if present, buffer layer 102 comprises a polymer film according to the present invention, that is, a polymer film comprising a mixture of:
   (i) an electrically conductive polymer, and
   (ii) anisotropic electrically conductive nanostructures.

The electronic device of the present invention may be any device that comprises one or more layers of semiconductor materials and makes use of the controlled motion of electrons through such one or more layers, such as, for example:

a device that converts electrical energy into radiation, such as, for example, a light-emitting diode, light emitting diode display, diode laser, or lighting panel,
a device that detects signals through electronic processes, such as, for example, a photodetector, photoconductive cell, photoresistor, photoswitch, phototransistor, phototube, infrared (“IR”) detector, or biosensor,
a device that converts radiation into electrical energy, such as, for example, a photovoltaic device or solar cell, and
a device that includes one or more electronic components with one or more semiconductor layers, such as, for example, a transistor or diode.

In one embodiment, the electronic device of the present invention is a device for converting electrical energy into radiation, and comprises an anode 101 that comprises a polymer film according to the present invention, a cathode layer 106, an electroactive layer 104 that is capable of converting electrical energy into radiation, disposed between the anode layer 101 layer and the cathode layer 106, and optionally further comprising a buffer layer 102, a hole transport layer 103, and/or an electron injection layer 105. In one embodiment, the device is a light emitting diode (“LED”) device and the electroactive layer 104 of the device is an electroluminescent material, even more typically, and the device is an organic light emitting diode (“OLED”) device and the electroactive layer 104 of the device is organic electroluminescent material. In one embodiment, the OLED device is an “active matrix” OLED display, wherein, individual deposits of photoactive organic films may be independently excited by the passage of current, leading to individual pixels of light emission. In another embodiment, the OLED is a “passive matrix” OLED display, wherein deposits of photoactive organic films may be excited by rows and columns of electrical contact layers.

In one embodiment, the electronic device of the present invention is a device for converting radiation into electrical energy, and comprises an anode 101 that comprises a polymer film according to the present invention, a cathode layer 106, an electroactive layer 104 comprising a material that is capable of converting radiation into electrical energy, disposed between the anode layer 101 layer and the cathode layer 106, and optionally further comprising a buffer layer 102, a hole transport layer 103, and/or an electron injection layer 105.

In operation of one embodiment of device 100, such as a device for converting electrical energy into radiation, a voltage from an appropriate power supply (not depicted) is applied to device 100 so that an electrical current passes across the layers of the device 100 and electrons enter electroactive layer 104, and are converted into radiation, such as in the case of an electroluminescent device, a release of photon from electroactive layer 104.

In operation of another embodiment of device 100, such as device for converting radiation into electrical energy, device 100 is exposed to radiation impinges on electroactive layer 104, and is converted into a flow of electrical current across the layers of the device.

### Examples 1-5 and Comparative Example C1

The compositions of Examples 1-5 and Comparative Example C1 were made as follows. 1 g isopropyl alcohol was mixed with 8 g of an aqueous dispersion containing 1.3 wt % of poly(3,4-ethylenedioxythiophene: poly(styrene sulfonic acid) (Clevios PH 1000, H.C. Starck “PEDOT:PSS”). In each case, a 0.1 g of a respective organic salt selected from pyridinium p-toluene sulfonate, pyridinium tribromide, pyridinium 3-nitrobenzene sulfonate, sodium benzene-1,3-disulfonate, and sodium-tetrakis(pentafluorophenyl)borate, was dissolved in 0.9 g dimethyl sulfoxide (Sigma Aldrich, “DMSO”) and the DMSO/organic salt solution was then added to the Isopropyl alcohol/PEDOT:PSS solution and stirred to form the coating compositions of Examples 1-5. The composition of Comparative Example C1 was made in an analogous way, except that no salt was included in the composition of Comparative Example C1. Each of the compositions of Examples 1-5 and Comparative Example C1 was spin-coated at 2000 revolutions per minute on a glass substrate to form a film of the composition. The spin-coated films were then annealed for 15 minutes at 90° C. The sheet resistance of each film was measured using four probe tester (Jandel RM3-AR) and the transmittance at 550 nm of each spin-coated films was characterized with a Cary 100 Bio UV-Visible spectrophotometer. The amounts of the ingredients used, the Sheet Resistance in ohms per square (Q/□), and the transmittance at 550 nm (as a percent (%)) are summarized for each of Examples 1-5 and Comparative Example C1 in TABLE I below.

TABLE I

| | | | | | | | | | | | CEX | |
|---|---|---|---|---|---|---|---|---|---|---|---|---|
| | EX 1 | | EX 2 | | EX 3 | | EX 4 | | EX 5 | | C1 | |
| 1.3% PEDOT:PSS | 8 | pbw | 8 | pbw | 8 | pbw | 8 | pbw | 8 | pbw | 8 | pbw |
| Isopropyl alcohol | 1 | pbw | 1 | pbw | 1 | pbw | 1 | pbw | 1 | pbw | 1 | pbw |
| DMSO | 0.9 | pbw | 0.9 | pbw | 0.9 | pbw | 0.97 | pbw | 0.9 | pbw | 0.9 | pbw |

| | | | | | | | |
|---|---|---|---|---|---|---|---|
| Pyridinium p-toluene | 0.1 | pbw | — | — | — | — | — |
| sulfonate | | | | | | | |

| | | | | | | | |
|---|---|---|---|---|---|---|---|
| Pyridinium tribromide | — | 0.1 | pbw | — | — | — | — |

| | | | | | | | |
|---|---|---|---|---|---|---|---|
| Pyridinium 3- | — | — | 0.1 | pbw | — | — | — |
| nitrobenzene sulfonate | | | | | | | |

| | | | | | | | |
|---|---|---|---|---|---|---|---|
| Sodium benzene-1,3-disulfonate | — | — | — | 0.03 | pbw | — | — |

| | | | | | | | |
|---|---|---|---|---|---|---|---|
| Sodium-tetrakis | — | — | — | — | 0.1 | pbw | — |
| (pentafluorophenyl)borate | | | | | | | |

| | | | | | | |
|---|---|---|---|---|---|---|
| Sheet Resistance (Ω/□) | 110 | 140 | 130 | 180 | 125 | 250 |
| Transmittance at 550 nm (%) | 93 | 93 | 94 | 94 | 93 | 96 |

### Examples 6 and Comparative Example C2

The compositions of Example 6 and Comparative Example C2 were made by mixing dimethyl sulfoxide (Sigma Aldrich, “DMSO”) or DMSO and sodium tetrakis(pentafluorophenyl) borate with an aqueous dispersion containing 1.3 wt % of poly(3,4-ethylenedioxythiophene: poly(styrene sulfonic acid) blend (Clevios PH 1000, H.C. Starck “PEDOT:PSS”), in the relative amounts set forth in TABLE II below.

The respective compositions were each spin-coated on glass substrates at 4000 revolutions per minute (“rpm”) to form a film of the composition. The spin-coated substrates were then annealed for 15 minutes at 90° C.

The resistance of each of the spin-coated films was measured between two electrodes of silver paste on opposite sides of a theoretical square, using a multimeter. The optical transmittance of the spin-coated films were characterized with a Cary 100 Bio UV-Visible spectrophotometer. The transmittance at 550 nm, in units of percent transmittance (%), for Example 6 and Comparative Example C2 are set forth in TABLE II below. The addition of sodium tetrakis(pentafluorophenyl) borate, was found to increase the surface roughness of the cast films and such films showed a lower apparent transmittance to increased light scattering.

TABLE II

| | Ex 6 | CEx C2 |
|---|---|---|
| Ingredient | | |
| PEDT:PSS | 89.5 | 90 |
| DMSO | 10 | 10 |
| Sodium-tetrakis | 0.5 | — |
| (pentafluorophenyl)borate | | |
| Property | | |
| Transmittance @ 550 nm (%) | 97.5 | 98.5 |

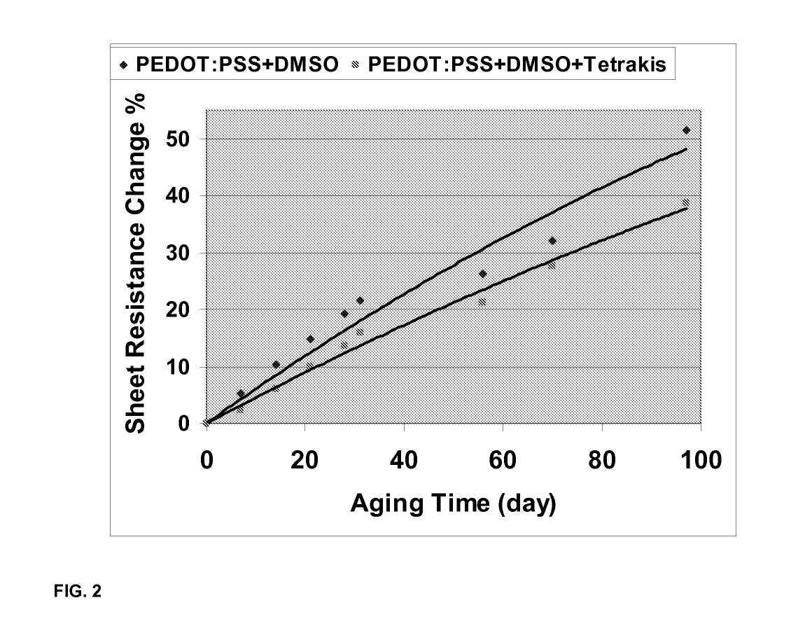

The films of Example 6 and Comparative Example C2 were aged and the sheet resistance of each of the films was measured periodically. FIG. 2 shows a comparison of the relative change in Sheet Resistance (as %) vs. ageing time (in days) for the PEDOT:PSS/DMSO/sodium tetrakis (pentafluorophenyl) borate film of Example 6 and the PEDOT:PSS/DMSO film of Comparative Example C2. The film of Example 6 showed a smaller relative increase in sheet resistance with ageing than the film of Comparative Example C2.

What is claimed is:

1. A polymer film, comprising a mixture of:
(a) at least one electrically conductive polymer, and
(b) at least one organic salt having a melting point of greater than 100° C.

2. The film of claim 1, wherein the electrically conductive polymer comprises a mixture of a polythiophene polymer and a polymeric acid dopant.

3. The polymer film of claim 2, wherein the polythiophene polymer comprises two or more monomeric units according to structure (I.a) per molecule of the polymer: 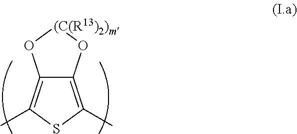
wherein:
each occurrence of R¹³ is independently H, alkyl, hydroxyl, heteroalkyl, alkenyl, heteroalkenyl, hydroxalkyl, amidosulfonate, benzyl, carboxylate, ether, ether carboxylate, ether sulfonate, ester sulfonate, or urethane, and
m′ is 2 or 3.
and the polymeric acid dopant comprises poly((styrene sulfonate).

4. The polymer film of claim 2, wherein the organic salt comprises pyridinium p-toluene sulfonate, pyridinium tribromide, pyridinium 3-nitrobenzene sulfonate, sodium benzene-1,3-disulfonate, sodium tetrakis (pentafluorophenyl) borate, or a mixture thereof.

5. The polymer film of claim 1, wherein the film exhibits a sheet resistance of less than or equal to 100 Ohms per square.

6. The polymer film of claim 1, wherein the film exhibits an optical transmittance at 550 nm of greater than or equal to 50%.

7. The polymer film of claim 1, wherein the film is supported on a substrate.

8. A polymer composition, comprising:
(a) a liquid carrier comprising water and at least one water miscible polar organic liquid,
(b) at least one electrically conductive polymer dissolved or dispersed in the liquid carrier, and
(c) at least one organic salt having a melting point of greater than 100° C. dissolved in the liquid carrier.

9. The polymer composition of claim 8, wherein:
(a) the at least one water miscible polar organic liquid comprises dimethyl sulfoxide,
(b) the at least one electrically conductive polymer comprises a mixture of:
(i) a polythiophene polymer that comprises two or more monomeric units according to structure (I.a) per molecule of the polymer: 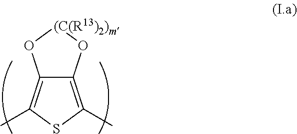
wherein:
each occurrence of R¹³ is independently H, alkyl, hydroxyl, heteroalkyl, alkenyl, heteroalkenyl, hydroxalkyl, amidosulfonate, benzyl, carboxylate, ether, ether carboxylate, ether sulfonate, ester sulfonate, or urethane, and
m′ is 2 or 3, and
(ii) a polymeric acid dopant that comprises poly((styrene sulfonate), and
(c) the at least one organic salt comprises pyridinium p-toluene sulfonate, pyridinium tribromide, pyridinium 3-nitrobenzene sulfonate, sodium benzene-1,3-disulfonate, sodium tetrakis (pentafluorophenyl) borate, or a mixture thereof.

10. A method for making polymer film, comprising:
(1) forming a layer of a polymer composition, said polymer composition comprising
(a) a liquid carrier comprising water and at least one water miscible polar organic liquid,
(b) at least one electrically conductive polymer dissolved or dispersed in the liquid carrier, and
(c) at least one organic salt having a melting point of greater than 100° C. dissolved in the liquid carrier, and
(2) removing the liquid carrier from the layer.

11. The method of claim 10, wherein:
(a) the at least one water miscible polar organic liquid comprises dimethyl sulfoxide,
(b) the at least one electrically conductive polymer comprises a mixture of:
(i) a polythiophene polymer that comprises two or more monomeric units according to structure (I.a) per molecule of the polymer: 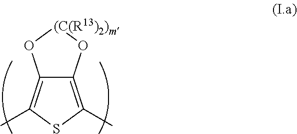
wherein:
each occurrence of R¹³ is independently H, alkyl, hydroxyl, heteroalkyl, alkenyl, heteroalkenyl, hydroxalkyl, amidosulfonate, benzyl, carboxylate, ether, ether carboxylate, ether sulfonate, ester sulfonate, or urethane, and
m′ is 2 or 3, and
(ii) a polymeric acid dopant that comprises poly((styrene sulfonate), and
(c) the at least one organic salt comprises pyridinium p-toluene sulfonate, pyridinium tribromide, pyridinium 3-nitrobenzene sulfonate, sodium benzene-1,3-disulfonate, sodium tetrakis (pentafluorophenyl) borate, or a mixture thereof.

12. A polymer film made by the method of claim 10.

13. An electronic device, comprising:
(a) an anode or combined anode and buffer layer 101,
(b) a cathode layer 106,
(c) an electroactive layer 104, disposed between anode layer 101 and cathode layer 106,
(d) optionally, a buffer layer 102,
(e) optionally, a hole transport layer 105, and
(f) optionally, an electron injection layer 105,
wherein at least one of at least one of the anode or combined anode and buffer layer 101, the cathode layer 106, and, if present, buffer layer 102 comprises a polymer film according to claim 1.
